(19) United States
(12) Patent Application Publication
(10) Pub. No.: US 2015/0261095 A1
(43) Pub. Date: Sep. 17, 2015

(54) Radiation Source

(71) Applicants: Bastiaan Stephanus Hendricus Jansen, Waalre (NL); Jan Frederik Hoogkamp, Breda (NL)

(72) Inventors: Bastiaan Stephanus Hendricus Jansen, Waalre (NL); Jan Frederik Hoogkamp, Breda (NL)

(73) Assignee: ASML Netherlands B.V., Veldhoven (NL)

(21) Appl. No.: 14/349,883

(22) PCT Filed: Sep. 6, 2012
(86) PCT No.: PCT/EP2012/067439

§ 371 Date: Apr. 4, 2014

Related U.S. Application Data
(60) Provisional application No. 61/544,317, filed on Oct. 7, 2011.

(51) Int. Cl. G03F 7/20

(52) U.S. Cl. CPC G03F 7/70033

(57) ABSTRACT

A radiation source suitable for providing a beam of radiation to an illuminator of a lithographic apparatus. The radiation source comprises a nozzle configured to direct a stream of fuel droplets along a trajectory towards a plasma formation location. The radiation source is configured to receive a first amount of radiation such that, in use, the first amount of radiation is incident on a fuel droplet at the plasma formation location, and such that, in use, the first amount of radiation transfers energy to the fuel droplet to generate a radiation generating plasma that emits a second amount of radiation. The radiation source further comprises a first sensor arrangement configured to measure a property of the first amount of radiation that is indicative of a focus position of the first amount of radiation; and a second sensor arrangement configured to measure a property of a fuel droplet that is indicative of a position of the fuel droplet.

### CROSS-REFERENCE TO RELATED APPLICATIONS FIELD

This application claims the benefit of U.S. provisional application 61/544,317 which was filed on Oct. 10, 2011 which is incorporated herein in its entirety by reference.

### FIELD

The present invention relates to a lithographic apparatus and a method for manufacturing a device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k₁ is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k₁.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm, for example within the range of 5-10 nm such as 6.7 nm or 6.8 nm. Possible sources include, for example, laser-produced plasma sources, discharge plasma sources, or sources based on synchrotron radiation provided by an electron storage ring.

EUV radiation may be produced using a plasma. A radiation source for producing EUV radiation may include a laser for exciting a fuel to provide the plasma, and a source collector module for containing the plasma. The plasma may be created, for example, by directing a laser beam at a fuel, such as particles of a suitable material (e.g., tin), or a stream of a suitable gas or vapor, such as Xe gas or Li vapor. The laser beam that is directed at the fuel may be an Infra Red (IR) laser (i.e., a laser that emits radiation at an IR wavelength), such as a Carbon Dioxide (CO2) laser or a Yttrium Aluminium Garnet (YAG) laser. The resulting plasma emits output radiation, e.g., EUV radiation, which is collected using a radiation collector. The radiation collector may be a mirrored normal incidence radiation collector, which receives the radiation and focuses the radiation into a beam. The source collector module may include an enclosing structure or chamber arranged to provide a vacuum environment to support the plasma. Such a radiation system is typically termed a laser produced plasma (LPP) source.

As discussed above, within LPP sources radiation is directed at a fuel. The properties of the radiation that is output by the radiation producing plasma depend upon the alignment between the fuel and the focus of the radiation that is directed at the fuel. For example, two properties of the radiation output by the radiation producing plasma that are affected by the alignment between the fuel and the focus of the radiation directed at the fuel are the total intensity and the intensity distribution of the radiation output by the radiation producing plasma. It will be appreciated that in certain applications of the radiation source it is beneficial for the intensity distribution of the radiation output by the radiation producing plasma to be substantially uniform. Furthermore, certain lithographic apparatus may require a particular intensity distribution of radiation is produced by the radiation source and it is desirable that such an intensity distribution is reproducible. For these reasons, it is desirable to have some indication of the relative alignment between the focus of the radiation directed at the fuel.

The ability to have some indication of the relative alignment between the focus of the radiation directed at the fuel may be beneficial due to the fact that it may be desirable to control the LPP source so that the radiation output from the radiation source has a desired distribution. Alternatively, or in addition, it may be desirable to have an indication of the relative alignment between the fuel and the focus of the radiation directed at the fuel due to the fact that both the position of the fuel and the position of the focus of the radiation directed at the fuel may be subject to external disturbances. For example, the focus position of the radiation directed at the fuel and the position of the fuel (and hence the alignment between the fuel and the focus of the radiation directed at the fuel) may be affected by system dynamics of the lithographic apparatus, such as the movement of parts of the lithographic apparatus. The ability to have an indication of the relative alignment between the fuel and the focus of the radiation directed at the fuel means that any misalignment between the fuel and the focus of the radiation directed at the fuel can be corrected.

In some known lithographic apparatus, the relative alignment between the fuel and the focus of the radiation directed at the fuel is measured indirectly. For example, a sensor referred to as a quad sensor may be used to measure the intensity distribution of the radiation output by the radiation producing plasma. By measuring the intensity distribution of the radiation output by the radiation producing plasma, it is possible to infer information about the relative alignment between the fuel and the focus of the radiation directed at the fuel. The quad sensor has four sensor elements that are located within the radiation source and that are equi-angularly spaced about an optical axis of the radiation output by the radiation producing plasma. By measuring the intensity of the radiation output by the radiation producing plasma that is incident on each sensor element, it is possible to determine the intensity distribution of the radiation output by the radiation producing plasma. As previously discussed, by measuring the intensity distribution of the radiation output by the radiation producing plasma, it is possible to infer information about the relative alignment between the fuel and the focus of the radiation directed at the fuel. This information relating to the relative alignment between the fuel and the focus of the radiation directed at the fuel may be used to correct any misalignment between the fuel and the focus of the radiation directed at the fuel.

There are various problems associated with this method of determining information about the relative alignment between the fuel and the focus of the radiation directed at the fuel. These problems are discussed below.

First, due to the fact that information about the relative alignment between the fuel and the focus of the radiation directed at the fuel is obtained by measuring properties of the radiation output by the radiation producing plasma, the determination of the information concerning the alignment between the fuel and the focus of the radiation directed at the fuel is dependent upon the interaction between the fuel and the radiation that is incident on the fuel, as well as on the properties of the radiation producing plasma.

The specifics of the interaction between the fuel and the radiation incident on the fuel, and also the properties of the radiation producing plasma, are not well known. For this reason, it is not possible to predict with absolute certainty what the alignment between the fuel and the focus of the radiation directed at the fuel based on measuring properties of the radiation output by the radiation producing plasma. Furthermore, due to the properties of the radiation producing plasma, for any given alignment between the fuel and the focus of the radiation directed at the fuel, the measured intensity/intensity distribution of the radiation output by the radiation producing plasma may be time-varying. Furthermore, the relationship between the alignment between the fuel and the focus of the radiation directed at the fuel and the measured intensity/intensity distribution of the radiation output by the radiation producing plasma may be non-linear. For this reason, measuring the properties of the radiation output by the radiation producing plasma makes it difficult to predict the relative alignment between the fuel and the focus of the radiation directed at the fuel with a high degree of accuracy.

The lack of accuracy in being able to determine the relative alignment between the fuel and the focus of the radiation directed at the fuel may make such a system for determining the relative alignment between the focus and the fuel unsuitable for high bandwidth control (i.e., control loops that operate at a high frequency).

Secondly, determining information regarding the relative alignment between the fuel and the focus of the radiation directed at the fuel by measuring a property of the radiation output by the radiation producing plasma requires that the radiation producing plasma is producing radiation, a property of which can be measured. When there is no output radiation being generated by the plasma (for example, if the fuel has not yet had radiation incident upon it) then it will not be possible to measure any property of radiation output by the radiation producing plasma, and as such it will not be possible to infer any information about the relative alignment between the focus of the radiation directed at the fuel. This may lead to additional start-up and/or recovery time for a lithographic apparatus that includes a radiation source that operates in this manner. Any additional start-up and/or recovery time of the lithographic apparatus is time in which the lithographic apparatus is not producing a product, and hence this reduces the output efficiency of the lithographic apparatus.

Thirdly, the sensing elements of the quad sensor that is used to measure properties of the radiation output of the radiation producing plasma are exposed to the radiation output by the radiation producing plasma. This may be disadvantageous in a situation whereby the radiation output by the radiation producing plasma is detrimental to the sensing elements of the quad sensor. For example, in the case where the radiation output by the radiation producing plasma is EUV radiation, the EUV radiation may damage the sensing elements of the quad sensor over time, thereby causing the quad sensor to degrade. The damage or degradation of the quad sensor over time may cause the sensing characteristics of the quad sensor to vary over time such that the output of the quad sensor becomes either inaccurate or incapable of producing useful information about the relative alignment between the fuel and the focus of the radiation directed at the fuel. Furthermore, in extreme circumstances, the quad sensor may be damaged or degrade to the extent that it is no longer operable.

Some known lithographic apparatus utilises radiation that is incident on the fuel that is produced by a Master Oscillator Power Amplifier (MOPA) laser. These lithographic apparatus may have a radiation source that functions differently to that previously described. In these cases, the production of output radiation from a fuel is a two-step process. The first step is that a first pulse of radiation is directed at the fuel such that the first amount of radiation is incident on the fuel, and converts the fuel into a modified fuel distribution. For example, the modified fuel distribution may be a cloud of partially plasmarised fuel. Subsequently, a second amount of radiation may be directed at the modified fuel distribution such that the second amount of radiation is incident on the modified fuel distribution, causing the modified fuel distribution to become a radiation producing plasma that outputs the desired radiation.

The first amount of radiation incident on the fuel may be referred to as a pre-pulse and the second amount of radiation incident on the modified fuel distribution may be referred to as a main-pulse.

In cases involving a pre-pulse and a main-pulse, both the relative alignment between the focus of the pre-pulse and the fuel, and the relative alignment between the focus of the main-pulse and the modified fuel distribution may be important in determining properties of the radiation output by the radiation producing plasma (for example, the intensity or the intensity distribution of the radiation output by the radiation producing plasma). Furthermore, it is thought that because the size of the fuel upon which the pre-pulse is incident is small compared to the size of the modified fuel distribution upon which the main-pulse is incident, it is likely that it is the relative alignment between the focus of the pre-pulse and the fuel that will be more critical than the alignment between the focus of the main-pulse and the modified fuel distribution to the properties of the radiation that is output by the radiation producing plasma.

However, as previously discussed, due to the fact that the pre-pulse radiation that is incident on the fuel will not create a radiation producing plasma, very little or no radiation will be produced as a result of the pre-pulse being incident on the fuel. Consequently, very little or no radiation will be measured by the quad sensor and hence the quad sensor is not capable of providing any information about the relative alignment between the focus of the pre-pulse and the fuel. Furthermore, due to the fact that the properties of the modified fuel distribution are not well understood, it may not be possible to determine information about the relative alignment between the focus of the main-pulse and the modified fuel distribution by measuring the intensity distribution of the output radiation produced by the radiation producing plasma.

The properties of the radiation output by the radiation producing plasma that are measured by the quad sensors are dependent on many factors other than the relative alignment between the fuel and the focus of the radiation directed at the fuel. For example, the properties of the radiation output by the radiation producing plasma that are measured by the quad sensor may be affected by properties of the radiation collector within the radiation source and by the location of the fuel relative to the radiation collector when the fuel becomes a radiation producing plasma. Because of this, it may be difficult to determine what the exact effect of the alignment between the fuel and the focus of the radiation directed at the fuel is on the properties of the radiation that is produced by the radiation source (and subsequently directed to parts of the lithographic apparatus which are downstream of the radiation source by the radiation collector). This makes it difficult to determine whether it is the alignment between the fuel and the focus of the radiation directed at the fuel or other properties of the radiation source that are affecting the properties of the radiation emitted by the radiation source in a particular way.

### SUMMARY OF THE INVENTION

It is desirable to provide a radiation source that obviates or mitigates at least one of the problems of the prior art whether described above or otherwise. It is also desirable to provide an alternative radiation source.

According to an aspect of the invention, there is provided a radiation source suitable for providing a beam of radiation to an illuminator of a lithographic apparatus, the radiation source comprising a nozzle configured to direct a stream of fuel droplets along a trajectory towards a plasma formation location; and the radiation source being configured to receive a first amount of radiation such that, in use, the first amount of radiation is incident on a fuel droplet at the plasma formation location, and such that, in use, the first amount of radiation transfers energy to the fuel droplet to generate a radiation generating plasma that emits a second amount of radiation; the radiation source further comprising a first sensor arrangement configured to measure a property of the first amount of radiation that is indicative of a focus position of the first amount of radiation; and a second sensor arrangement configured to measure a property of a fuel droplet that is indicative of a position of the fuel droplet.

The first sensor arrangement may be configured to measure a property of the first amount of radiation at a first time that is indicative of the focus position of the first amount of radiation at a second time; and wherein the second sensor arrangement is configured to measure a property of the fuel droplet at a third time that is indicative of the position of the fuel droplet at the second time.

The first and third times may be before the second time.

The first sensor arrangement may comprise a reflector arrangement and a sensor element; the reflector arrangement comprising a sensor reflector, at least part of which is located in the path of the first amount of radiation, upstream of the focus position of the first amount of radiation, an which reflects a portion of the first amount of radiation towards the sensor element.

The second sensor arrangement may comprise a position sensor configured to output a position signal that is indicative of a position of the fuel droplet.

The position signal may be indicative of a position of the fuel droplet at the third time.

The position sensor may be an image sensor that images a portion of the trajectory along which the stream of fuel droplets is directed, in use, by the nozzle towards the plasma formation location.

The second sensor arrangement may comprise a timing sensor configured to output a timing signal that is indicative of the time at that the fuel droplet passes a trigger point along the trajectory along which the stream of fuel droplets is directed, in use, by the nozzle towards the plasma formation location.

The time at that the fuel droplet passes the trigger point may be the third time.

The second sensor arrangement may comprise: a position sensor configured to output a position signal that is indicative of a position of the fuel droplet; and a timing sensor configured to output a timing signal that is indicative of the time at which the fuel droplet passes a trigger point along the trajectory along which the stream of fuel droplets is directed, in use, by the nozzle towards the plasma formation location; and optionally wherein the position sensor is an image sensor that images a portion of the trajectory along which the stream of fuel droplets is directed, in use, by the nozzle towards the plasma formation location.

The position sensor may be configured to output a position signal that is indicative of a position of the fuel droplet at the third time; and wherein the position signal that is indicative of a position of the fuel droplet at the third time and the time at which the fuel droplet passes the trigger point are both indicative of the position of the fuel droplet at the second time.

The radiation source may further comprise a radiation directing device that is configured to direct the first amount of radiation and thereby determine the focus position of the first amount of radiation.

The radiation directing device may comprise a directing reflector, at least part of which, in use, is located in the path of the first amount of radiation, and at least one reflector actuator, which is mechanically linked to the directing reflector, and whereby movement of the at least one reflector actuator changes the orientation and/or position of the directing reflector relative to the path of the first amount of radiation.

The nozzle may be mechanically linked to at least one nozzle actuator, whereby movement of the at least one nozzle actuator changes the position of the nozzle relative to the remainder of the radiation source, and hence the trajectory of the stream of fuel droplets.

The radiation source may comprise a secondary radiation source, the secondary radiation source generating the first amount of radiation; and a timing controller connected to the secondary radiation source and configured to control the time at which the secondary radiation source generates the first amount of radiation.

The radiation source may further comprise a controller, and wherein the first sensor arrangement provides a first sensor signal to the controller, the second sensor arrangement provides a second sensor signal to the controller; and wherein the controller is arranged to control at least one of the plasma formation location, the focus position of the first amount of radiation and the trajectory of the stream of fuel droplets; based on the first and second sensor signals.

The radiation source may further comprise a nozzle actuator that is mechanically linked to the nozzle, a radiation directing device that is configured to direct the first amount of radiation and thereby determine the focus position of the first amount of radiation, the radiation directing device having a radiation directing device actuator, and a controller, the controller being configured to implement a first control scheme for controlling the radiation source in a direction perpendicular to the trajectory of the fuel droplets; the first control scheme comprising a first relatively fast control loop and a first relatively slow control loop, the first relatively fast control loop controlling the radiation directing device actuator based on first sensor arrangement and the controller, the first relatively slow control loop controlling the nozzle actuator based on the second sensor arrangement and the controller; and wherein the first relatively fast control loop tracks the first relatively slow control loop.

The radiation source may further comprise a secondary radiation source, the secondary radiation source generating the first amount of radiation; and a timing controller connected to the secondary radiation source and configured to control the time at which the secondary radiation source generates the first amount of radiation, the timing controller being controlled, in use, by the controller, the controller being configured to implement a second control scheme for controlling the radiation source in a direction parallel to the trajectory of the fuel droplets; the second control scheme comprising a second relatively fast control loop and a second relatively slow control loop, the second relatively fast control loop controlling the timing controller based on the second sensor arrangement and the controller, the second relatively slow control loop controlling the radiation device directing actuator based on the first sensor arrangement and the controller; and wherein the first relatively fast control loop tracks the first relatively slow control loop.

According to a further aspect of the invention there is provided a lithographic apparatus arranged to project a pattern from a patterning device onto a substrate, wherein the lithographic apparatus comprises a radiation source configured to provide a beam of radiation to the patterning device, the radiation source comprising:

a nozzle configured to direct a stream of fuel droplets along a trajectory towards a plasma formation location; and

the radiation source being configured to receive a first amount of radiation such that, in use, the first amount of radiation is incident on a fuel droplet at the plasma formation location, and such that, in use, the first amount of radiation transfers energy into the fuel droplet to generate a modified fuel distribution or a radiation generating plasma that emits a third amount of radiation;

a first sensor arrangement configured to measure a property of the first amount of radiation that is indicative of a focus position of the first amount of radiation; and

a second sensor arrangement configured to measure a property of a fuel droplet that is indicative of a position of the fuel droplet.

Further features and advantages of the present invention, as well as the structure and operation of various embodiments of the present invention, are described in detail below with reference to the accompanying drawings. It is noted that the present invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 depicts the lithographic apparatus of FIG. 1 in more detail;

FIG. 3 is a schematic plan view of a radiation source according to an embodiment of the invention that forms part of the lithographic apparatus shown in FIGS. 1 and 2;

FIG. 4 shows a control loop;

FIGS. 5 and 6 show control schemes that form part of an embodiment of the invention; and

FIG. 7 shows a schematic diagram of a scan path of a focus position that may be used to calibrate a radiation source according to an embodiment of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

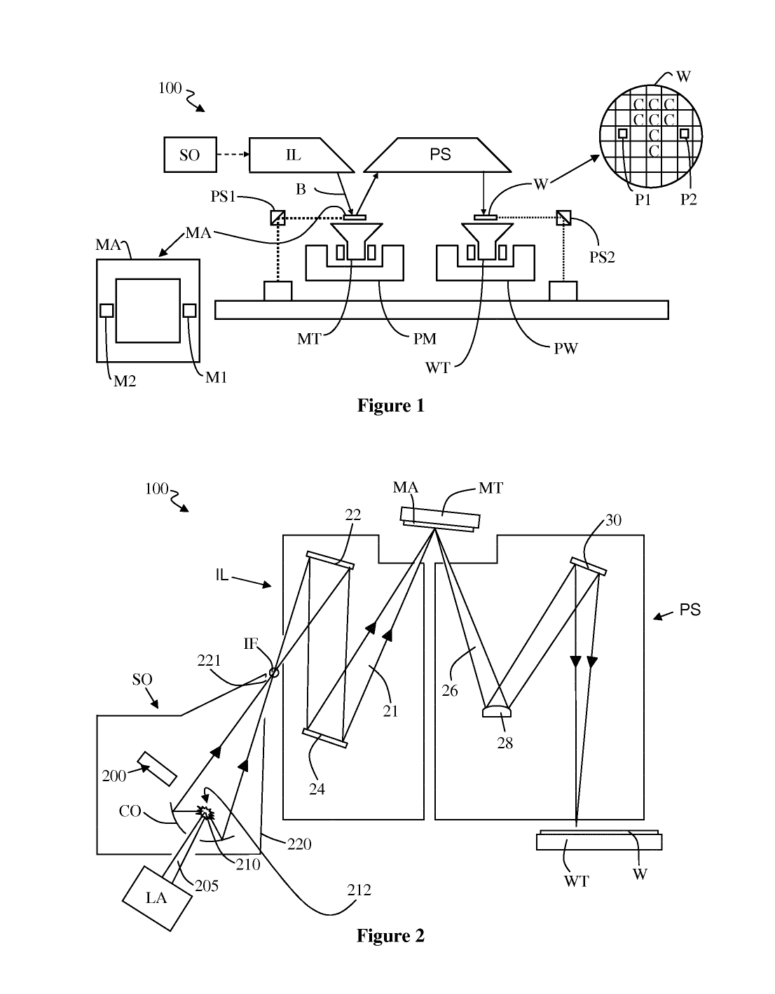

FIG. 1 schematically depicts a lithographic apparatus 100 including a source collector module SO according to one embodiment of the invention. The apparatus comprises:
an illumination system (illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam that is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since gases may absorb too much radiation. A vacuum environment may therefore be provided to the whole beam path with the aid of a vacuum wall and vacuum pumps.

As here depicted, the apparatus is of a reflective type (e.g., employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultraviolet (EUV) radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel with a laser beam. Fuel may for example be a droplet, stream or cluster of material having the required line-emitting element. The source collector module SO may be part of an EUV radiation system including a laser, not shown in FIG. 1, for providing the laser beam that excites the fuel. The resulting plasma emits output radiation, e.g., EUV radiation, which is collected using a radiation collector located in the source collector module. The laser and the source collector module may be separate entities, for example when a CO₂ laser is used to provide the laser beam for fuel excitation. In such cases, the laser is not considered to form part of the lithographic apparatus, and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using mask alignment marks M1, M2 and substrate alignment marks P1, P2.

The depicted apparatus could be used in at least one of the following modes:

1. In step mode, the support structure (e.g., mask table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

2. In scan mode, the support structure (e.g., mask table) MT and the substrate table WT are scanned synchronously while a pattern imparted to the radiation beam is projected onto a target portion C (i.e., a single dynamic exposure). The velocity and direction of the substrate table WT relative to the support structure (e.g., mask table) MT may be determined by the (de-)magnification and image reversal characteristics of the projection system PS.

3. In another mode, the support structure (e.g., mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

FIG. 2 shows the apparatus 100 in more detail, including the source collector module SO, the illumination system IL, and the projection system PS. The source collector module SO is constructed and arranged such that a vacuum environment can be maintained in an enclosing structure 220 of the source collector module SO. The source collector module may also be referred as a radiation source.

A secondary radiation source, in this case a laser LA, is arranged to deposit energy via a first amount of radiation (in this case laser beam 205) into a fuel, such as xenon (Xe), tin (Sn) or lithium (Li), which is provided from a fuel supply 200, thereby creating a highly ionized plasma 210 at a plasma formation location with electron temperatures of several 10's of eV. The laser LA may emit infra red (IR) radiation. The energetic radiation generated during de-excitation and recombination of these ions is emitted from the plasma, collected and focussed by a near normal incidence collector optic CO. The laser may operate in a pulsed manner.

Radiation that is reflected by the collector optic CO is focused in a virtual source point IF. The virtual source point IF is commonly referred to as the intermediate focus, and the source collector module SO is arranged such that the intermediate focus IF is located at or near an opening 221 in the enclosing structure 220. The virtual source point IF is an image of the radiation emitting plasma 210.

Subsequently the radiation traverses the illumination system IL. The illumination system IL may include a facetted field mirror device 22 and a facetted pupil mirror device 24 arranged to provide a desired angular distribution of the radiation beam 21 at the patterning device MA, as well as a desired uniformity of radiation intensity at the patterning device MA. Upon reflection of the beam of radiation 21 at the patterning device MA, a patterned beam 26 is formed and the patterned beam 26 is imaged by the projection system PS via reflective elements 28, 30 onto a substrate W held by the substrate table WT.

More elements than shown may generally be present in the illumination system IL and projection system PS. Further, there may be more mirrors present than those shown in the Figures, for example there may be 1-6 additional reflective elements present in the projection system PS than shown in FIG. 2.

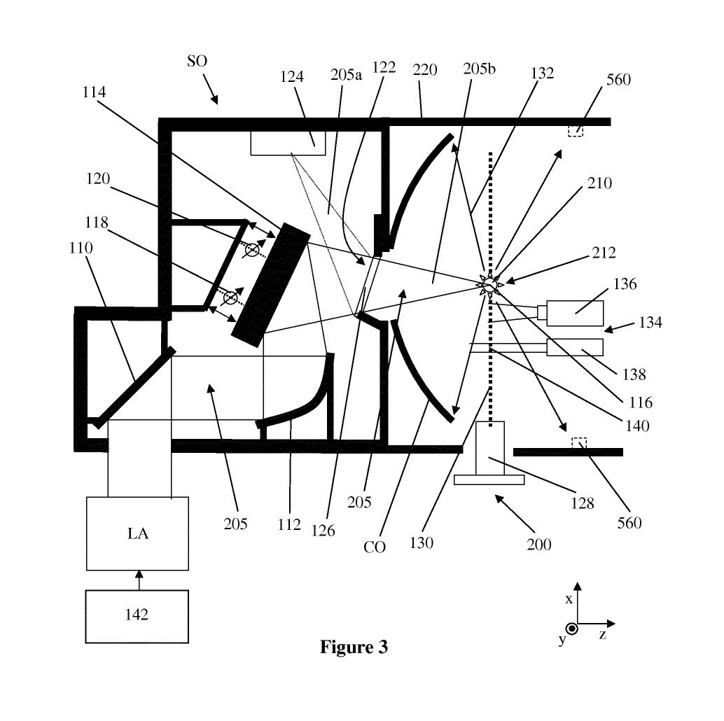

FIG. 3 shows the radiation source SO in more detail. The radiation source SO comprises two fixed reflective elements 110, 112 and a moveable reflective element 114, which collectively direct and focus the first amount of radiation (also referred to as a beam of radiation 205) towards a focus position 116 of the radiation beam 205. The moveable reflector element 114 forms part of a radiation directing device. The reflector element 114 (or reflector) of the radiation directing device is located in the path of the radiation beam 205 (also referred to as a first amount of radiation). The radiation directing device also comprises at least one reflector actuator, which is mechanically linked to the reflector 114. In this case, the radiation directing device comprises two reflector actuators 118, 120, which are mechanically linked to the reflector 114. Movement of at least one of the reflector actuators 118, 120 changes the orientation and/or position of the reflector 114 relative to the path of the beam of radiation 205. In this way, the reflector actuator can be actuated in order to adjust the orientation and/or position of the reflector 114 relative to the radiation beam 205 so as to alter the focus position 116 of the beam of radiation 205.

It will be appreciated that although two reflector actuators 118, 120 have been shown in the present embodiment, in other embodiments there may be any appropriate number of reflector actuators provided there is at least one reflector actuator. Furthermore, it will be appreciated that in the present embodiment the reflector actuators 118, 120 change the orientation and/or position of the reflector 114 relative to the radiation beam 205. However, in other embodiments, the actuator(s) may alter any appropriate property of the reflector that will alter the focus position of the radiation beam. For example, the actuator(s) may change the shape of the reflector. Finally, the radiation directing device of the present embodiment comprises a reflector 114. In other embodiments, the radiation directing device may comprise any appropriate directing element that is capable of altering the focus position of the radiation beam. For example, the radiation directing device may comprise a plurality of lens elements, the properties of each lens element being adjustable.

The radiation source SO also comprises a first sensor arrangement. The first sensor arrangement comprises a reflector arrangement 122 and a sensor element 124. The reflector arrangement comprises a sensor reflector 126. At least part of the sensor reflector 126 is located in the path of the first amount of radiation (radiation beam 205). It can be seen that the sensor reflector 126 is located upstream of the focus position 116 of the radiation beam 205 (having regard to the direction of travel of the beam of radiation 205 from the laser LA). The sensor reflector 126 reflects a first portion 205a of the radiation beam towards the sensor element 124 such that the first portion 205a of the radiation beam is incident on the sensor element 124. The sensor reflector 126 is only partially reflective of the radiation of the laser beam 205 such that only a portion of the radiation beam 205 is reflected by the sensor reflector 126 (so as to constitute the first portion of the radiation beam 205a). Some of the radiation of the radiation beam 205 passes through the sensor reflector 126 and constitutes a second portion 205b of the radiation beam 205. It is the second portion of the radiation beam 205b that converges to a focus at the focus point 116. In some embodiments the sensor reflector 126 is configured such that the power of the first portion 205a of the radiation beam that is reflected by the sensor reflector 126 is less than the power of the second portion 205b of the radiation beam that passes through the sensor reflector 126.

It will be appreciated that in other embodiments of the present invention, the sensor reflector may not be in the path of the entire cross-section of the radiation beam 205. For example, the sensor reflector may only be in the path of part of the radiation beam 205. In some embodiments the sensor reflector may only be in the path of an edge portion of the radiation beam such that the sensor reflector only reflects said edge portion of the radiation beam. In some embodiments of the present invention the first sensor arrangement may not comprise a sensor reflector. In such embodiments, a sensor element may be located directly in the path of at least a portion of the radiation beam. Also the first sensor arrangement may comprise any appropriate number of sensor elements. For example, the first sensor arrangement may comprise a plurality of edge detection sensor elements that are located in the path of separate edge portions of the radiation beam 205.

The sensor element 124 of the first sensor arrangement may be a Charge Coupled Device (CCD) or a Position Sensitive Device (PSD).

As previously discussed, the radiation source SO comprises a fuel supply 200. The fuel supply 200 has a nozzle 128 that is configured to direct a stream of fuel droplets along a trajectory 130 towards a plasma formation location 212.

The fuel supply 200 and hence the nozzle 128 are moveable relative to the rest of the radiation source SO (and in particular relative to the radiation collector CO) by at least one actuator (not shown). The at least one actuator is mechanically linked to the fuel supply 200 and nozzle 128. The trajectory 140 of the fuel droplet is parallel to an x-axis. The x-axis is marked on FIG. 3 for ease of reference. The x-axis extends in a direction that is generally from the bottom of the Figure to the top of the Figure. A z-axis, which is perpendicular to the x-axis, extends in a direction that is generally from the left of the page to the right of the page. A y-axis that is perpendicular to both the x-axis and the z-axis extends generally out of the plane of the page.

The fuel supply 200 and hence nozzle 128 of the present embodiment are moveable by the actuators (not shown) within the y-z plane. That is to say, the fuel supply 200 and nozzle 128 are not moveable in the direction parallel to the x-axis. However, it will be appreciated that in other embodiments of the invention, the fuel supply and nozzle may be moveable in a direction parallel to the x-axis. Furthermore, in other embodiments of the invention, the fuel supply 200 and nozzle 128 may be tilted relative to the x-axis.

In use the radiation source SO receives a first amount of radiation (in this case the radiation beam 205 from the laser LA) such that the first amount of radiation is incident on a fuel droplet (not shown) that has been dispensed from the nozzle 128 and which is located at the plasma formation location 212. At the plasma formation location 212, the first amount of radiation is incident on the fuel droplet (not shown) so that the first amount of radiation transfers energy to the fuel droplet so as to generate a radiation generating plasma 210 that emits a second amount of radiation 132.

In this case the second amount of radiation 132 is EUV radiation, but it will be appreciated that in other embodiments the second amount of radiation may be any appropriate type of radiation. The second amount of radiation is focused and directed out of the radiation source SO towards the illuminator of the lithographic apparatus by the source collector CO. The source collector CO may also be referred to as a radiation collector.

It will be appreciated that the fuel droplet that has become the radiation producing plasma 210 is not shown within FIG. 3. This is because FIG. 3 shows the radiation source SO at a time after the first amount of radiation has transferred energy into the fuel droplet such that the fuel droplet has become the radiation producing plasma 210. It will also be appreciated that before the fuel droplet became the radiation producing plasma, the fuel droplet was located substantially at the plasma formation location 212. That is to say, when the first amount of radiation is incident on the fuel droplet such that the first amount of radiation transfers energy to the fuel droplet, the fuel droplet is located substantially at the plasma formation location 212.

It will be appreciated that although the secondary radiation source (the laser LA) is part of the radiation source SO in this embodiment of the invention, in other embodiments of the invention this need not be the case. For example, the secondary radiation source may be separate to the radiation source.

The radiation source SO has a second sensor arrangement 134. The second sensor arrangement comprises a position sensor 136 and a timing sensor 138. In this case, the position sensor 136 is an image sensor that images a portion of the trajectory 130 intermediate the nozzle 128 and the plasma formation location 212. In other embodiments, the image sensor may image the plasma formation location. The image sensor may be a camera. In some embodiments of the invention the image sensor may also include a radiation source that directs radiation at the area to be imaged by the image sensor.

The timing sensor 138 may take the form of a laser curtain. The laser curtain may have at least one laser beam that is directed across the trajectory 130 of the fuel droplet towards a pick-up sensor (now shown). When a fuel droplet passes through the at least one laser beam of the laser curtain, the intensity of the laser beam measured by the pick-up sensor changes and hence the timing sensor 138 detects that an object (in this case a fuel droplet) has passed through the laser curtain. It will be appreciated that although the timing sensor of the current embodiment comprises a laser curtain, in other embodiments of the invention other timing sensors may be used provided they are capable of detecting the time of an event at which a fuel droplet travelling along its trajectory 130 passes a particular point along the trajectory 130.

The position sensor of the second sensor arrangement outputs a position signal that is indicative of the position of the fuel droplet. The timing sensor 138 of the second sensor arrangement 134 outputs a timing signal that is indicative of the time at which the fuel droplet passes a trigger point 140 along the trajectory 130 of the fuel droplet.

As discussed, the timing sensor outputs a timing signal that is indicative of the time at which the fuel droplet passes the trigger point 140 along the trajectory 130. Due to the fact that the trigger point 140 is at a known position along an x-axis, the time at which the fuel droplet passes the trigger point 140, in combination with the speed of travel of the fuel droplet, can be used to determine the position of the fuel droplet along the x-axis at a time, which is after the time at which the fuel droplet passes the trigger point 140. The x-axis, as shown in FIG. 3, lies parallel to the trajectory of the fuel droplet.

The image sensor 134 may image the portion of the trajectory 130 such that the position sensor outputs a position signal that is indicative of the location of the fuel droplet in a y-z plane when the fuel droplet is imaged by the image sensor. The y-z plane is a plane that lies parallel to the plane containing both the y and z axes. The y and z axes (as shown in FIG. 3) are perpendicular to one another and to the x axis.

The timing signal output by the timing sensor 138 (which is indicative of the time at which the fuel droplet passes a trigger point 140 along the trajectory 130, and which therefore indicates the time at which the fuel droplet is at a particular position along the x-axis) in combination with the position signal that is indicative with a position of the fuel droplet (in the y-z plane when the fuel droplet is imaged), and information about the speed and direction of travel of the fuel droplet can be combined so as to determine the position of the fuel droplet at a time that is after the time at which the fuel droplet passes the trigger point and the time at which the fuel droplet is imaged so as to output the position signal. Consequently, the position of the fuel droplet relative to the rest of the radiation source SO (and in particular the radiation collector CO) at any time after the time at which the fuel droplet passes the trigger point 140 and after the image sensor images a portion of the trajectory 130, can be determined.

From the description of the embodiment above, it is clear that the first sensor arrangement is configured to measure a property of the first amount of radiation (i.e., the radiation beam 205) that is indicative of the focus position 116 of the first amount of radiation. In this case, the property of the first amount of radiation that is measured by the sensor element 124 of the first sensor arrangement is the position of the first portion 205a of the radiation beam that is reflected by the sensor reflector 126.

The second sensor arrangement is configured to measure a property of the fuel droplet that is indicative of a position of the fuel droplet. In the case of the present embodiment, two properties of the fuel droplet are measured that are indicative of a position of the fuel droplet. First, the timing sensor 138 of the second sensor arrangement 134 measures the time at which the fuel droplet passes the trigger point 140 along the trajectory 130. This is indicative of the position of the fuel droplet along the x-axis at the time when the fuel droplet passes the trigger point 140. Secondly, the property of the fuel droplet that is measured by the position sensor 136 of the second sensor arrangement 134 is the position of the fuel droplet in the y-z plane at the time when the position sensor images the portion of the trajectory 130.

The first sensor arrangement may be configured such that the time at which the first sensor arrangement measures the property of the first amount of radiation that is indicative of the focus position 116 (in this case the position of the first, reflected portion of the radiation beam 205a) concurrently with the time at which the first amount of radiation reaches the focus position 116. Alternatively, the first sensor arrangement may be configured to measure a property of the first amount of radiation at a first time that is indicative of the focus position of the first amount of radiation at a second time that is different to the first time. For example, the first sensor arrangement may measure a property of the first amount of radiation at a position that is upstream of the focus position 116 such that the property of the first amount of radiation is measured by the first sensor arrangement at a time that is before the time at which the first amount of radiation reaches the focus position 116.

The second sensor arrangement is configured to measure a property of the fuel droplet at a third time that is indicative of the position of the fuel droplet at the second time. In this case, the second time is the time at which the first amount of radiation reaches the focus position 116. Provided the radiation source is correctly calibrated, the second time will also be the time at which the fuel droplet substantially reaches the plasma formation location 212.

In the present example, the third time is a time before the second time due to the fact that the trigger point 140 along the trajectory 130 and the portion of the trajectory 130 that is imaged by the image sensor are both upstream of the plasma formation location 212 relative to the direction of travel of the fuel droplet. It will be appreciated that in other embodiments of the present invention the image sensor may image a portion of the trajectory 130 such that the image sensor images the fuel droplet at the time and position where the first amount of radiation is incident on the fuel droplet.

It will be appreciated that although the present embodiment of the invention shows a second sensor arrangement 134 having a position sensor 136 and a timing sensor 138, in other embodiments the second sensor arrangement may have only a position sensor or a timing sensor. In these embodiments the position sensor or the timing sensor may measure the respective position of the fuel droplet or time at which the fuel droplet passes the trigger point at the third time.

The radiation source SO may also have a timing controller 142 that is connected to the secondary radiation source (in this case the laser LA). The timing controller 142 is configured so as to control the time at which the secondary radiation source generates the first amount of radiation (in this case radiation being 205).

The timing controller 142 controls the secondary radiation source such that the secondary radiation source generates the first amount of radiation at a time such that the first amount of radiation reaches the focus position 116 at the same time that the fuel droplet is located at the focus position 116. Consequently, the first amount of radiation is incident on the fuel droplet and energy is transferred from the first amount of radiation to the fuel droplet such that the fuel droplet becomes the radiation generating plasma 210. Consequently, the position at which the fuel droplet becomes the radiation generating plasma 210 is the plasma formation location.

The radiation source SO may also have a controller (not shown), which may be referred to as the radiation source controller. The radiation source may then be configured such that the first sensor arrangement provides a first sensor signal to the controller and the second sensor arrangement provides a second sensor signal to the controller. The radiation source controller is arranged to control at least one of the plasma formation location, the focus position of the first amount of radiation and the trajectory of the stream of fuel droplets. The radiation source controller controls the at least one of the plasma formation location, the focus position of the first amount of radiation and the trajectory of the stream of fuel droplets based on the first and/or second sensor signals. In some embodiments the radiation source controller may control the plasma formation location, the focus position of the first amount of radiation and the trajectory of the stream of fuel droplets based on the first and second sensor signals.

In order to control the focus position of the first amount of radiation, the controller may provide a first control signal to the reflector actuators 118, 120 to thereby control the orientation and/or position of the directing reflector 114 relative to the path of the first amount of radiation 205. In order to control the trajectory 130 of the stream of fuel droplets, the controller may provide a second control signal to the actuator that is mechanically linked to the fuel supply 200 and nozzle 128. In order to control the plasma formation location, the controller may provide control signals to at least one of the timing controller 142, the reflector actuators 118, 120 and the at least one actuator that is mechanically linked to the fuel supply 200.

By controlling the laser timing, the orientation of the reflector 114 relative to the beam of radiation 205 and the position/orientation of the fuel supply 200 (the direction of the trajectory 130) independently, it is possible to not only control the relative alignment between the fuel droplet and the focus 116 of the beam of radiation 205, but also the absolute position of the plasma formation location 212 relative to the rest of the radiation source SO, and in particular the radiation collector CO. For example, if it was desired to locate the plasma location formation 212 at a particular position relative to the radiation collector CO, then first the actuator that is mechanically linked to the fuel supply 200 (and hence nozzle 128) would be actuated by the second control signal from the controller so that the nozzle 128 points in the direction such that the trajectory 130 of the fuel droplet passes through the desired plasma formation location 212. The controller would then send a first control signal to the reflector actuators 118, 120 so as to orientate/position/shape the reflector relative to the beam of radiation 205 such that the focus position 116 of the beam of radiation 205 is located at the desired plasma formation location 212. Finally, the controller sends a control signal to the timing controller 142 of the secondary radiation source such that the secondary radiation source emits the first amount of radiation (radiation beam 205) at a time such that the first amount of radiation reaches the focus position (i.e., the desired plasma formation location 212) at the same time that the fuel droplet reaches the desired plasma formation location 212. It will be appreciated that although these three steps have been described in a particular order in relation to the current embodiment of the invention, in other embodiments the steps may be carried out in any appropriate order or simultaneously.

The radiation source according to the present invention differs from known radiation sources in several ways. First the prior art radiation sources detect a property (for example the intensity distribution) of the radiation emitted by the radiation producing plasma in order to try to determine information about the relative alignment between the fuel droplet and the focus position of the first amount of radiation. The radiation source according to the present invention independently measures a property of the first amount of radiation that is indicative of the focus position of the first amount of radiation, and a property of the fuel droplet that is indicative of the position of the fuel droplet. In the embodiment shown, the property of the first amount of radiation is measured directly. That is to say, a portion of the first amount of radiation is directed towards the sensing element of the first sensor arrangement where it is sensed by the sensing element of the first sensor arrangement. In the case of the second sensor arrangement, which measures a property of the fuel droplet that is indicative of the position of the fuel droplet, the property in question is a position of the fuel droplet that is measured by two separate sensors (the position sensor and the timing sensor).

As previously discussed, by measuring both the focus position of the first amount of radiation and the position of the fuel droplet independently, it is possible to control not only the relative alignment between the focus position of the first amount of radiation and the fuel droplet, but also the location of the plasma formation location relative to the radiation collector CO. The ability to control these factors separately means that, compared to the prior art, not only is there a greater accuracy in determining and controlling the relative alignment between the focus position of the first amount of radiation and the fuel droplet, but also there is greater control in the properties (for example intensity distribution) of the radiation that is output by the radiation producing plasma (and hence the radiation source).

Unlike the prior art, in order to determine/control the relative alignment between the focus position of the first amount of radiation and the fuel droplet the radiation source according to the present invention does not measure a property of the radiation output by the radiation producing plasma. It follows that in order to measure the relative alignment between the focus position of the first amount of radiation and the fuel droplet, the radiation source according to the present invention does not require radiation to be produced by the radiation producing plasma. This may lead to reduced start-up and/or recovery time for a lithographic apparatus, which includes a radiation source according to the present invention.

Also, because a property the radiation output by the radiation producing plasma is not measured by a radiation source according to the present invention in order to determine the relative alignment between the focus position of the first amount of radiation and the fuel droplet, the sensors used to measure the relative alignment are not exposed to the radiation output by the radiation producing plasma. In this way, if the radiation output by the radiation producing plasma is damaging to sensors, then the sensors will not be exposed to this damaging radiation.

Furthermore, the radiation source according to the present invention will be suitable for use with radiation generating methods that utilise a pre-pulse and a main pulse.

As previously discussed, the radiation source according to the present invention has the ability to monitor the focus position 116 using the first sensing arrangement, and in particular the sensing element 124. The focus position 116 can be adjusted by using the reflector actuators 118, 120. Similarly, the fuel droplet position can be monitored by the second sensor arrangement, in particular the timing sensor 138 and the position 136. The position of the fuel droplet can be changed by changing the trajectory 130 of the fuel droplet. This is achieved by controlling the actuator that is mechanically linked to the fuel supply 200 and hence the nozzle 128. Finally, the timing controller 142 can be controlled so as to determine the time at which the first amount of radiation (radiation beam 205) reaches the focus position 116.

As previously discussed, the present invention allows both the relative alignment between the focus position and the fuel droplet, and the position of the plasma formation location relative to the radiation collector to be measured and controlled independently. It has been found by the applicant that, in relation to a radiation source that produces an output radiation that has desirable properties (for example a desirable total intensity and/or intensity distribution), the relative alignment between the focus position and the fuel droplet is of greater significance than the position of the plasma formation location relative to the radiation collector. For this reason the applicant has determined that it is beneficial for the relative alignment between the focus position and the fuel droplet to be controlled to a greater accuracy compared to the control of the position of the plasma formation location relative to the radiation collector.

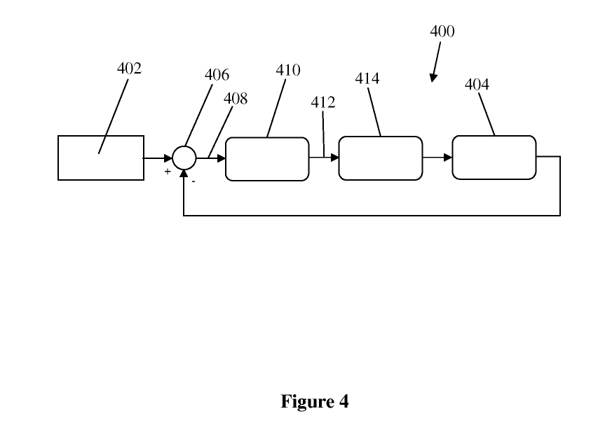

FIG. 4 shows a control loop for a dynamic system. The control loop 400 has a desired output of a system that is referred to as a reference and is indicated by block 402. A sensor 404 measures the current state of the system and a comparator 406 compares the state of the system measured by the sensor 404 with the reference 402. The difference between the state of the system measured by the sensor 404 and the reference 402 is determined by the comparator 406 and the comparator 406 provides a measured error 408 to a controller 410. The controller determines a system input 412 based on the measured error 408 and provides the system input 412 to a portion of the system 414. The portion of the system 414 may include an actuator or other type of effector that is capable of altering the output of the system that is measured by the sensor 404 and for which the reference 402 provides a desired value. It will be appreciated that over the course of time the reference (i.e., the value of the desired output of the system) may change. The controller 410 of the control loop 400 controls the portion of the system 414 so as to try to ensure that the desired property of the system is as close as possible to the reference.

As previously discussed, it has been found by the applicant that the control of the alignment between the focus position and the fuel droplet is more significant to the output performance of the radiation source than the position of the plasma formation location relative to the radiation collector. Consequently, the applicant has determined that it is beneficial for the control loop that controls the alignment between the focus position and the fuel droplet to be faster than the control loop that controls the position of the plasma formation location relative to the radiation collector. That is to say that the control loop that controls the alignment between the focus position and the fuel droplet takes less time to complete a circuit of the control loop than the control loop that controls the position of the plasma formation location relative to the radiation collector

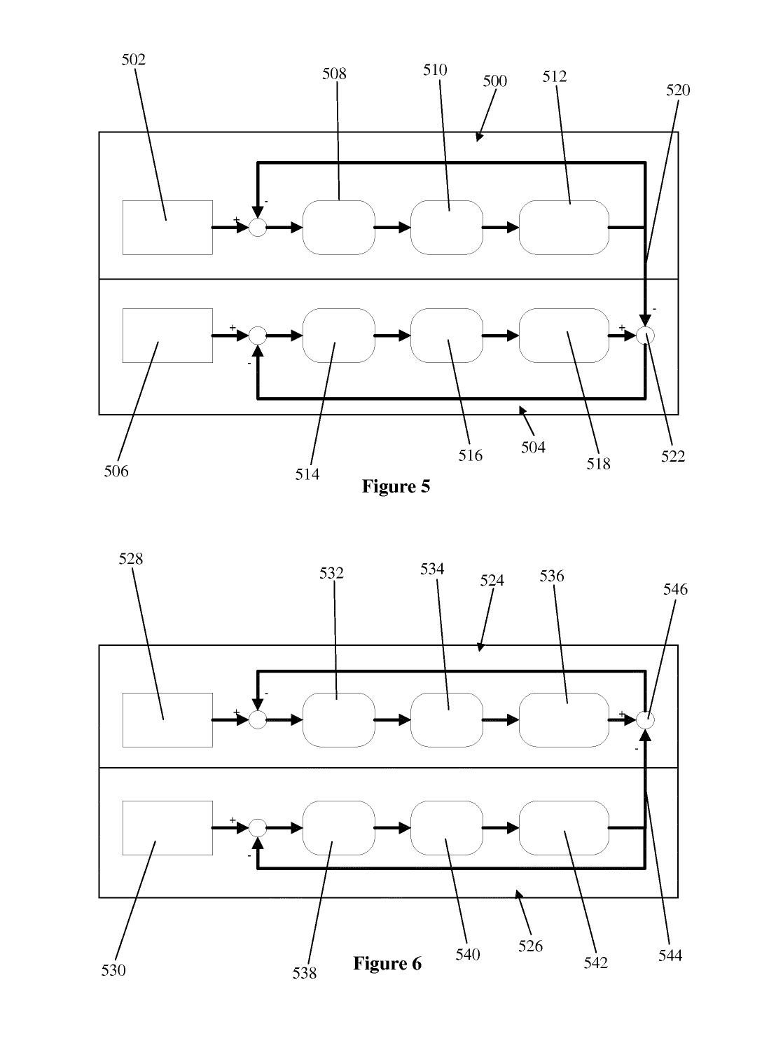

FIGS. 5 and 6 show two separate control schemes for controlling a radiation source according to the present invention.

FIG. 5 shows a control scheme that is used to control the radiation source in a direction perpendicular to the trajectory of the fuel droplets. Referring briefly to FIG. 3, it can be seen that the trajectory 130 of the fuel droplets within this Figure is parallel to the x-axis. It follows that the control scheme shown in FIG. 5 is used to control the system in relation to the positioning of the focus position and the droplet position within a plane parallel to that containing the y and z axes as shown in FIG. 3.

The control scheme shown in FIG. 5 has two interlinked control loops. The first control loop 500 relates to controlling the position of the plasma formation location relative to the radiation collector. Consequently, the reference 502 of the control loop 500 is a desired position of the plasma formation location relative to the radiation collector. The second control loop 54 relates to controlling the relative alignment between the focus of the first amount of radiation and the fuel droplet. Consequently, the reference 506 of the second control loop 504 is a desired alignment between the focus of the first amount of radiation and the fuel droplet. As previously discussed, in order to enhance the output performance of the radiation source, it is desirable that the control loop controlling the relative alignment between the focus of the first amount of radiation and the fuel droplet (in this case control loop 504) is faster than the control loop controlling the position of the plasma formation location relative to the radiation collector (in this case the first control loop 500).

As previously discussed, the control scheme shown in FIG. 5 relates to the control of the radiation source in a direction perpendicular to the trajectory of the fuel droplets. In directions perpendicular to the trajectory of the fuel droplets, the control of the focus position of the first amount of radiation is typically faster than the control of the position of the fuel droplet because the flight time of the fuel droplets along the trajectory from the position that the fuel droplets are generated (i.e., the nozzle) to the position at which the position of the fuel droplets is measured, limits the speed (also referred to as bandwidth) at which the control of the droplet position can be carried out. For this reason, the first control loop 500, which is the relatively slow control loop that controls the position of the plasma formation location relative to the radiation collector, relates to controlling the position of the fuel droplet. As a result, the first control loop 500 comprises a fuel droplet position controller 508, a droplet position actuator 510 and a fuel droplet position sensor 512. In this case, the fuel droplet position controller 508 may form part of the radiation source controller. The fuel droplet position actuator 510 comprises the at least one actuator that is mechanically linked to the fuel supply 200 and hence nozzle 128. The fuel droplet position sensor 512 comprises the position sensor 136 of the second sensor arrangement 134.

As previously discussed, the control of the focus position of the first amount of radiation in the direction perpendicular to the trajectory of the droplet is faster than the control of the position of the fuel droplet. The second control loop 504, which is the relatively fast control loop that controls the relative alignment between the focus position of the first amount of radiation and the fuel droplet, includes a focus position controller 514, a focus positioning actuator 516 and a focus position sensor 518. In this case, the focus position controller may form part of the radiation source controller. The focus positioning actuator comprises the reflector actuators 118, 120. The focus position sensor 518 includes the sensing element 124 of the first sensor arrangement.

It can be seen that an output 520 of the first control loop is fed to a comparator 522, the comparator 522 being part of the relatively fast second control loop 504 that controls the relative alignment between the focus of the first amount of radiation and the droplet. In this way, the relatively slow plasma formation location control loop 500 provides an input to the relatively fast (and more significant to radiation source performance) control loop 504, which controls the relative alignment between the focus position of the first amount of radiation and the fuel droplet. It may also be said that because the control loop 500 provides an input to the control loop 504, the relatively fast control loop 504 tracks the relatively slow control loop 500.

FIG. 6 shows a control scheme that relates to the control of the radiation source in a direction that is parallel to the trajectory of the fuel droplet. As before, the control scheme has two interconnected control loops: a first control loop 524 and a second control loop 526. The first control loop 524 controls the relative alignment between the focus of the first amount of radiation and the fuel droplet. Consequently, the first control loop 524 has a reference 528 that is a desired relative alignment between the focus position of the first amount of radiation and the fuel droplet. The second control loop 526 controls the position of the plasma formation location relative to the radiation collector. Consequently, the second control loop 526 has a reference 530 that is a desired position of the plasma formation location relative to the radiation collector. As previously discussed, it is desirable for the control loop that controls the relative alignment between the focus of the first amount of radiation and the fuel droplet to have a greater accuracy than the control loop that controls the position of the plasma formation location relative to the radiation source. Consequently, the control loop 524 is relatively fast compared to the control loop 526.

In the direction parallel to the trajectory of the fuel droplet, typically, the control of the position of the fuel droplet is faster than the control of the position of the focus of the first amount of radiation. This is because, in the direction of the trajectory of the fuel droplet, the alignment between the first amount of radiation (for example, the focus of the first amount of radiation) and the fuel droplet can be controlled by controlling the timing of the secondary radiation source (in this case the laser LA) by the timing controller 142. The timing of the laser can be varied at a very high rate. For example, the timing of the laser (relative to the position of the fuel droplet) can be varied from pulse to pulse of the laser LA.

Due to the fact that, as previously discussed, the control of the droplet position (relative to the first amount of radiation) is faster in the direction parallel to the trajectory of the fuel droplet than the control of the position of the focus of the first amount of radiation, then relatively fast control loop 524 includes the control of the fuel droplet position. It follows that the relatively fast control loop 524, which controls the relative alignment between the focus of the first amount of radiation and the fuel droplet, includes a fuel droplet position controller 532, a fuel droplet position actuator 534 and a fuel droplet position sensor 536. The fuel droplet position controller 532 may form part of the radiation source controller. The fuel droplet position actuator includes the timing controller 142, which controls the timing of the secondary radiation source, the laser LA. The fuel droplet position sensor includes the timing sensor 138 of the second sensor arrangement 134.

The relatively slow control loop 526, which controls the position of the plasma formation location relative to the radiation collector, includes control of the focus position of the first amount of radiation. Consequently, the relatively slow control loop 526 includes a focus position controller 538, a focus positioning actuator 540 and a focus position sensor 542. In this case, the focus position controller 538 may be the radiation source controller. The focus positioning actuator 540 includes the reflector actuators 118, 120. The focus position sensor 542 includes the sensing element 124 of the first sensor arrangement.

In common with the control scheme shown in FIG. 5, the control scheme shown in FIG. 6 is such that the relatively slow control loop 526 has an output 544 that is fed to a comparator 546, which forms part of the relatively fast control loop 524. Consequently, the relatively slow control loop 526 (which relates to the control of the position of the plasma formation location) provides an input to the relatively fast control loop 524 (which controls the relative alignment between the focus of the first amount of radiation and the fuel droplet). In this manner, the relatively fast control loop 524 may be said to track the relatively slow control loop 526.

As previously discussed, the radiation source according to the present invention is capable of measuring the focus position of the first amount of radiation and measuring the position of the fuel droplet independently. Furthermore, based on these measurements, the radiation source according to the present invention is capable of controlling the position of the focus of the first amount of radiation, and controlling the position of the fuel droplet independently. Because of this, it may be necessary to initially calibrate the radiation source or subsequently recalibrate the radiation source. For example, it may be necessary to calibrate the first sensor arrangement and the second sensor arrangement (and possibly also the timing controller of the secondary radiation source) such that the system can be controlled so as to effectively control the alignment between the focus of the first amount of radiation and the fuel droplet, and control the position of the plasma formation location relative to the radiation collector. The calibration of the radiation source may involve providing the radiation source controller with information as to how the output of the first and second sensor arrangement, which are provided to the radiation source controller, relate to the actual position of the focus of the first amount of radiation and the position of the fuel droplet respectively.

Calibration of the measured focus position of the first amount of radiation measured by the first sensor arrangement and calibration of the measured fuel droplet position measured by the second sensor arrangement towards a single position reference may be accomplished as follows. The alignment between the focus position of the first amount of radiation and the fuel droplet may be varied in three controlled degrees of freedom. For example, the relative alignment between the focus position of the first amount of radiation and the fuel droplet may be varied in directions parallel to the x, y and z axes. This variation in each of the three controlled degrees of freedom may be carried out in the search for optimum plasma properties and hence optimum properties of the radiation output by the radiation source. For example, the variation may be carried out in the search for a maximum output power of the radiation output by the radiation source.

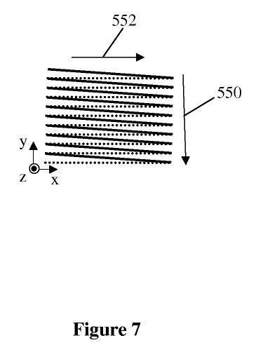

As shown in FIG. 7, one method of varying the relative alignment between the focus position of the first amount of radiation and the fuel droplet is to vary the alignment between the focus position of the first amount of radiation and the fuel droplet at a constant velocity in a direction that is perpendicular to the trajectory of the fuel droplets. Within FIG. 7 the trajectory of the fuel droplet is parallel to the x-axis. The relative alignment between the focus position of the first amount of radiation and the fuel droplet is varied with a constant velocity in a direction parallel to the y-axis indicated by the arrow 550. As previously discussed, the direction 550 is perpendicular to the trajectory of the fuel droplets (which in this case are parallel to the x-axis). Whilst the alignment between the focus position of the first amount of radiation and the fuel droplet is varied with a constant velocity, a sawtooth modulation is applied to the timing of the secondary radiation source in a direction that is parallel to the trajectory of the fuel droplet (in this case, a direction parallel to the x-axis). The sawtooth modulation of the laser timing is used to scan in a direction parallel to the trajectory of the fuel droplet. The scanning of the direction parallel to the trajectory of the fuel droplet by applying the sawtooth modulation to the timing of the secondary radiation source is indicated by arrow 552.

In this way a two dimensional plane (in this case a plane parallel to the plane containing both the x and y axes) can be scanned (i.e., such that the properties of the radiation output by the radiation source can be measured) with only a single constant velocity movement of either the focus position of the first amount of radiation or the droplet position so as to vary the relative alignment between the focus position of the first amount of radiation and the fuel droplet position.

It is also possible to balance the resolution of the scan within the two dimensional plane by controlling the frequency of the sawtooth modulation of the laser timing. That is to say, the modulation of the laser timing can be chosen such that the resolution of the scan in the x-direction is substantially the same as the resolution of the scan in the y-direction.

An alternative method of calibrating or recalibrating the relative alignment between the focus position of the first amount of radiation and the fuel droplet position is to add a further control loop to the control schemes shown in FIGS. 5 and 6 that adjusts the offset between the measured fuel droplet position and the measured focus position of the first amount of radiation based on a measured property of the radiation output by the radiation source. For example, quad sensors (shown in dashed line and indicated by 560 in FIG. 3) may be used to measure the intensity distribution of the radiation output by the radiation source, and this information may be used by the radiation source controller to adjust the offset between the measured fuel droplet position and the measured focus position for the first amount of radiation. In this set up, the quad sensors would only be used for calibration purposes (for example, recalibration due to drift correction), which will make the characteristics of the quad sensors (for example, their longevity and/or sensitivity) less critical than quad sensors used in the prior art.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

Although specific reference may have been made above to the radiation source forming part of a lithographic apparatus, it will be appreciated that the radiation source need not be limited to use within a lithographic apparatus. The radiation source may be used as a source of radiation in any appropriate application.

The term “lens”, where the context allows, may refer to any one or combination of various types of optical components, including refractive, reflective, magnetic, electromagnetic and electrostatic optical components.

The term “EUV radiation” may be considered to encompass electromagnetic radiation having a wavelength within the range of 5-20 nm, for example within the range of 13-14 nm, or example within the range of 5-10 nm such as 6.7 nm or 6.8 nm.

The term “IR radiation” may be considered to encompass electromagnetic radiation having a wavelength within the range of 0.6 and 500 nm, for example within the range of 1 and 15 μm, for example 10.6 μm.

While specific embodiments of the invention have been described above, it will be appreciated that the invention may be practised otherwise than as described. For example, the invention may take the form of a computer program containing one or more sequences of machine-readable instructions describing a method as disclosed above, or a data storage medium (e.g., semiconductor memory, magnetic or optical disk) having such a computer program stored therein. The descriptions above are intended to be illustrative, not limiting. Thus it will be apparent to one skilled in the art that modifications may be made to the invention as described without departing from the scope of the claims set out below.

1. A radiation source suitable for providing a beam of radiation to an illuminator of a lithographic apparatus, the radiation source comprising:
a nozzle configured to direct a stream of fuel droplets along a trajectory towards a plasma formation location;
the radiation source being configured to receive a first amount of radiation such that, in use, the first amount of radiation is incident on a fuel droplet at the plasma formation location, and such that, in use, the first amount of radiation transfers energy to the fuel droplet to generate a radiation generating plasma that emits a second amount of radiation;
the radiation source further comprising a first sensor arrangement configured to measure a property of the first amount of radiation that is indicative of a focus position of the first amount of radiation; and
a second sensor arrangement configured to measure a property of a fuel droplet that is indicative of a position of the fuel droplet.

2. The radiation source according to claim 1, wherein the first sensor arrangement is configured to measure a property of the first amount of radiation at a first time that is indicative of the focus position of the first amount of radiation at a second time; and
wherein the second sensor arrangement is configured to measure a property of the fuel droplet at a third time that is indicative of the position of the fuel droplet at the second time.

3. The radiation source according to claim 2, wherein the first and third times are before the second time.

4. The radiation source according to claim 1, wherein the first sensor arrangement comprises a reflector arrangement and a sensor element; the reflector arrangement comprising a sensor reflector, at least part of which is located in the path of the first amount of radiation, upstream of the focus position of the first amount of radiation, and which reflects a portion of the first amount of radiation towards the sensor element.

5. The radiation source according to claim 2, wherein the second sensor arrangement comprises a position sensor configured to output a position signal which is indicative of a position of the fuel droplet.

6. The radiation source according to claim 5, wherein the position signal is indicative of a position of the fuel droplet at the third time.

7. The radiation source according to claim 6, wherein the position sensor is an image sensor which images a portion of the trajectory along which the stream of fuel droplets is directed, in use, by the nozzle towards the plasma formation location.

8. The radiation source according to claim 2, wherein the second sensor arrangement comprises a timing sensor configured to output a timing signal which is indicative of the time at which the fuel droplet passes a trigger point along the trajectory along which the stream of fuel droplets is directed, in use, by the nozzle towards the plasma formation location.

9. The radiation source according to claim 8, wherein the time at which the fuel droplet passes the trigger point is the third time.

10. The radiation source according to claim 2, wherein the second sensor arrangement comprises:
a position sensor configured to output a position signal which is indicative of a position of the fuel droplet; and
a timing sensor configured to output a timing signal which is indicative of the time at which the fuel droplet passes a trigger point along the trajectory along which the stream of fuel droplets is directed, in use, by the nozzle towards the plasma formation location; and optionally
wherein the position sensor is an image sensor which images a portion of the trajectory along which the stream of fuel droplets is directed, in use, by the nozzle towards the plasma formation location.

11. The radiation source according to claim 10, wherein the position sensor is configured to output a position signal which is indicative of a position of the fuel droplet at the third time; and
wherein the position signal which is indicative of a position of the fuel droplet at the third time and the time at which the fuel droplet passes the trigger point are both indicative of the position of the fuel droplet at the second time.

12. The radiation source according to claim 1, wherein the radiation source further comprises a radiation directing device which is configured to direct the first amount of radiation and thereby determine the focus position of the first amount of radiation.

13. The radiation source according to claim 12, wherein the radiation directing device comprises a directing reflector, at least part of which, in use, is located in the path of the first amount of radiation, and at least one reflector actuator which is mechanically linked to the directing reflector, and whereby movement of the at least one reflector actuator changes the orientation and/or position of the directing reflector relative to the path of the first amount of radiation.

14. The radiation source according to claim 1, wherein the nozzle is mechanically linked to at least one nozzle actuator, whereby movement of the at least one nozzle actuator changes the position of the nozzle relative to the remainder of the radiation source, and hence the trajectory of the stream of fuel droplets.

15. The radiation source according to claim 1, wherein the radiation source comprises:
a secondary radiation source, the secondary radiation source generating the first amount of radiation; and
a timing controller connected to the secondary radiation source and configured to control the time at which the secondary radiation source generates the first amount of radiation.

16. The radiation source according to claim 1, wherein the radiation source further comprises a controller, and
wherein the first sensor arrangement provides a first sensor signal to the controller, the second sensor arrangement provides a second sensor signal to the controller; and
wherein the controller is arranged to control at least one of the plasma formation location, the focus position of the first amount of radiation and the trajectory of the stream of fuel droplets; based on the first and second sensor signals.

17. A lithographic apparatus arranged to project a pattern from a patterning device onto a substrate, wherein the lithographic apparatus comprises a radiation source configured to provide a beam of radiation to the patterning device, the radiation source comprising:
a nozzle configured to direct a stream of fuel droplets along a trajectory towards a plasma formation location;
the radiation source being configured to receive a first amount of radiation such that, in use, the first amount of radiation is incident on a fuel droplet at the plasma formation location, and such that, in use, the first amount of radiation transfers energy into the fuel droplet to generate a modified fuel distribution or a radiation generating plasma that emits a third amount of radiation;
a first sensor arrangement configured to measure a property of the first amount of radiation that is indicative of a focus position of the first amount of radiation; and
a second sensor arrangement configured to measure a property of a fuel droplet that is indicative of a position of the fuel droplet.

18. The radiation source according to claim 1, further comprising
a nozzle actuator that is mechanically linked to the nozzle,
a radiation directing device which is configured to direct the first amount of radiation and thereby determine the focus position of the first amount of radiation, the radiation directing device having a radiation directing device actuator,
and a controller,
the controller being configured to implement a first control scheme for controlling the radiation source in a direction perpendicular to the trajectory of the fuel droplets;
the first control scheme comprising a first relatively fast control loop and a first relatively slow control loop, the first relatively fast control loop controlling the radiation directing device actuator based on first sensor arrangement and the controller,
the first relatively slow control loop controlling the nozzle actuator based on the second sensor arrangement and the controller; and wherein the first relatively fast control loop tracks the first relatively slow control loop.

19. The radiation source according to claim 18, wherein the radiation source further comprises a secondary radiation source, the secondary radiation source generating the first amount of radiation; and
a timing controller connected to the secondary radiation source and configured to control the time at which the secondary radiation source generates the first amount of radiation, the timing controller being controlled, in use, by the controller,
the controller being configured to implement a second control scheme for controlling the radiation source in a direction parallel to the trajectory of the fuel droplets;
the second control scheme comprising a second relatively fast control loop and a second relatively slow control loop, the second relatively fast control loop controlling the timing controller based on the second sensor arrangement and the controller,
the second relatively slow control loop controlling the radiation device directing actuator based on the first sensor arrangement and the controller; and wherein the first relatively fast control loop tracks the first relatively slow control loop.

20-29. (canceled)

30. The radiation source according to claim 5, wherein the position sensor is an image sensor configured to image a portion of the trajectory along which the stream of fuel droplets is directed, in use, by the nozzle towards the plasma formation location.

31.-39. (canceled)
